(19) United States
(12) Patent Application Publication
(10) Pub. No.: US 2023/0243893 A1
(43) Pub. Date: Aug. 3, 2023

(54) BATTERY DEGRADATION PREDICTION DEVICE, BATTERY DEGRADATION PREDICTION SYSTEM, AND PREPARATION METHOD FOR BATTERY DEGRADATION PREDICTION

(71) Applicant: Mitsubishi Electric Corporation, Tokyo (JP)

(72) Inventors: Sho SHIRAGA, Tokyo (JP); Keisuke OGASAWARA, Tokyo (JP)

(73) Assignee: Mitsubishi Electric Corporation, Tokyo (JP)

(21) Appl. No.: 17/928,936

(22) PCT Filed: Jul. 8, 2020
(86) PCT No.: PCT/JP2020/026759

§ 371 Date: Dec. 1, 2022

(51) Int. Cl. G01R 31/392; G01R 31/382; G01R 31/367

(52) U.S. Cl. CPC G01R 31/392; G01R 31/382; G01R 31/367

(57) ABSTRACT

A battery degradation prediction device includes a battery monitoring device that monitors a charge rate SOC of a battery and a temperature T of the battery, and a computing device that computes a capacity residual rate f(t) of the battery on the basis of the charge rate SOC, the temperature T, and an elapsed time t from start of monitoring of the battery. The capacity residual rate f(t) is computed using a first function formula including a first formula. The first formula includes an exponential function having, as a variable, a value obtained by multiplying the elapsed time t by a degradation coefficient a and −1. The battery degradation prediction device predicts a degradation state of the battery on the basis of the capacity residual rate f(t) computed using the first function formula.

### FIELD

The present disclosure relates to a battery degradation prediction device for predicting a degradation state of a battery, a battery degradation prediction system, and a preparation method for battery degradation prediction.

### BACKGROUND

In a case where a battery is a lithium ion battery, in a conventional battery degradation prediction device, there are many techniques for computing a capacity residual rate of the battery on the basis of a degradation rate obtained from a square root of a use time and predicting a service life of the battery on the basis of the computed capacity residual rate, considering degradation of a negative electrode as a main factor.

In contrast to the conventional method described above, Patent Literature 1 below discloses a technique for estimating a capacity residual rate of a battery on the basis of a function formula obtained by combining degradation formulas of two types of positive and negative electrodes, additionally considering degradation of a positive electrode. Specifically, in the technique of Patent Literature 1, capacity degradation mainly caused by degradation of the positive electrode is expressed using an exponential function having, as a variable, a value obtained by multiplying a use time by a positive constant. Further, capacity degradation due to degradation of the negative electrode is expressed using a square root function for the use time.

### CITATION LIST

### Patent Literature

Patent Literature 1: Japanese Patent Application Laid-open No. 2013-254710

### SUMMARY

### Technical Problem

The degradation formula on the positive electrode side in the technique of Patent Literature 1 represents a degradation characteristic that rapidly changes at an end of service life of the battery, but does not represent a degradation characteristic of the positive electrode at an initial stage of storage. For this reason, the technique of Patent Literature 1 has a problem that the capacity residual rate cannot be accurately estimated particularly in a case of a battery including a degradation mechanism in which the capacity is reduced by elution of a component of the positive electrode into a battery solution. Therefore, in a case of a battery including a degradation mechanism caused by elution of an electrode component into a battery solution, in the technique of Patent Literature 1, it has been difficult to predict a degradation state of the battery.

The present disclosure has been made in view of the above, and an object is to obtain a battery degradation prediction device enabling prediction of a degradation state of a battery even in a case of a battery including a degradation mechanism caused by elution of an electrode component into a battery solution.

### Solution to Problem

In order to solve the above-described problem and achieve the object, a battery degradation prediction device according to the present disclosure is a battery degradation prediction device for predicting a degradation state of a battery including a first degradation mechanism in which a capacity is degraded by elution of a part of a component of an electrode of the battery into a solution of the battery. The battery degradation prediction device includes a battery monitoring device and a computing device. The battery monitoring device monitors a charge rate of the battery and a temperature of the battery. The computing device computes a capacity residual rate of the battery on the basis of the charge rate, the temperature, and an elapsed time from a start of monitoring the battery. The capacity residual rate is computed using a first function formula including a first formula. The first formula includes an exponential function having, as a variable, a value obtained by multiplying the elapsed time by a first degradation coefficient and −1. The battery degradation prediction device predicts a degradation state of the battery on the basis of the capacity residual rate computed using the first function formula.

### Advantageous Effects of Invention

The battery degradation prediction device according to the present disclosure has an effect of enabling prediction of a degradation state of a battery even in a case of a battery including a degradation mechanism caused by elution of an electrode component into a battery solution.

### BRIEF DESCRIPTION OF DRAWINGS

FIG. 1 is a diagram illustrating a configuration example of a battery degradation prediction system including a battery degradation prediction device according to a first embodiment.

FIG. 2 is a flowchart illustrating a processing flow of degradation prediction in the battery degradation prediction device according to the first embodiment.

FIG. 3 is a graph to be used to describe a preliminary experiment in the first embodiment.

FIG. 4 is a block diagram illustrating an example of a hardware configuration that implements functions of a computing device in the first embodiment.

FIG. 5 is a block diagram illustrating another example of a hardware configuration that implements functions of the computing device in the first embodiment.

FIG. 6 is a flowchart illustrating a processing flow of degradation prediction in a battery degradation prediction device according to a second embodiment.

### DESCRIPTION OF EMBODIMENTS

Hereinafter, a battery degradation prediction device, a battery degradation prediction system, and a preparation method for battery degradation prediction according to embodiments of the present disclosure will be described in detail with reference to the accompanying drawings.

### First Embodiment

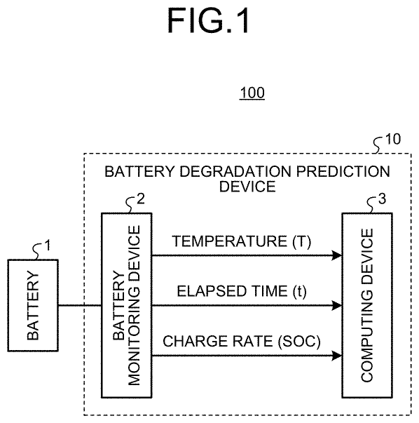

FIG. 1 is a diagram illustrating a configuration example of a battery degradation prediction system including a battery degradation prediction device according to a first embodiment. A battery degradation prediction system 100 according to the first embodiment includes a battery 1 and a battery degradation prediction device 10. The battery degradation prediction device 10 includes a battery monitoring device 2 and a computing device 3.

The battery 1 is a secondary battery capable of charging and discharging. An example of the secondary battery is a lithium ion battery. Hereinafter, a description is given assuming a case where the battery 1 is a lithium ion battery, but the present disclosure is not limited thereto. In a case where the battery 1 includes a capacity degradation mechanism caused by elution of a positive electrode component into a battery solution, the present disclosure can be applied to the battery. Other examples of the battery 1 include a lead accumulator, a nickel hydride battery, and the like.

It is known that a secondary battery such as a lithium ion battery is degraded even in an unused state, that is, in a state where charging and discharging are not performed. This degradation is called storage degradation. When the battery 1 is in a storage state without being used, an internal active material undergoes an oxidation-reduction reaction and is discharged little by little even if no current flows through an external circuit. The discharged electric charge has a reversible process that can be returned by charging and an irreversible process that leads to degradation without recovery. A degree of progress of the storage degradation varies depending on a charge rate and a temperature. The charge rate is also called a state of charge (SOC). Hereinafter, in the present specification, the charge rate is referred to as “SOC”. In addition, in the present specification, “SOC” may be treated as a symbol and described as a “charge rate SOC”.

In a case where degradation of the battery 1 progresses, a chargeable energy capacity decreases or maximum power that can be supplied decreases. In addition, in the battery 1, an electrode expands and contracts by repeating a charge-discharge cycle, and a degradation phenomenon such as peeling of the electrode material occurs due to a fatigue failure. Such degradation associated with charging and discharging is called cycle degradation. A degree of progress of the cycle degradation changes due to an influence of a current value at a time of charging and discharging, a temperature, a range of a charge rate of the cycle, and the like.

The battery monitoring device 2 monitors the charge rate SOC of the battery 1 and a temperature T of the battery 1. The computing device 3 receives information on the temperature T, an elapsed time t, and the charge rate SOC from the battery monitoring device 2. The elapsed time t is an elapsed time from when the battery monitoring device 2 starts monitoring the battery 1 or an elapsed time from previous reception to current reception. The computing device 3 computes a capacity residual rate f(t) of the battery 1 with Formula (1) below on the basis of the charge rate SOC, the temperature T, and the elapsed time t.

f(t)=exp(−a×t) (1)

In Formula (1) above, the capacity residual rate f(t) represents a ratio to an initial capacity of the battery 1 at the elapsed time t. If the capacity residual rate f(t) of the battery 1 is known, it is possible to predict a degradation state of the battery 1, that is, a degradation degree which is a degree of degradation.

The battery 1 according to the first embodiment includes a degradation mechanism in which a part of a component of an electrode is eluted into a solution of the battery 1 to degrade a capacity of the battery 1. In the present specification, this degradation mechanism is appropriately referred to as a “first degradation mechanism”. Formula (1) above is a formula considering the first degradation mechanism.

Further, a formula of “1−exp(−a×t)” obtained by modifying Formula (1) above is considered. This formula represents a degradation rate of an electrode in the first degradation mechanism. Note that, the positive electrode is mainly degraded in the first degradation mechanism. Therefore, in the following description, a description target is the positive electrode. Further, the degradation rate of the positive electrode may be referred to as a “first degradation rate”.

Next, a derivation procedure of Formula (1) above will be described. First, a reaction rate at which the electrode component is eluted into the battery solution is expressed by Formula (2) below as a primary reaction having dependency on time and a concentration of the electrode component.

−dC_{A}/dt=a×C_{A} (2)

In Formula (2) above, reference character “C_{A}” is a concentration of an electrode component, reference character “a” is a reaction rate constant, and reference character “t” is time.

By integrating Formula (2) above with t=0 and C_{A}=C_{A0}, Formula (3) below is expressed.

ln(C_{A}/C_{A0})=−a×t (3)

By modifying Formula (3) above, Formula (4) below is obtained.

C_{A}=C_{A0}×exp(−a×t) (4)

Therefore, in a graph in which a logarithmic value of “C_{A}/C_{A0}” is plotted with respect to time, a value of “−a” can be obtained from a gradient of a straight line connecting the plotted values.

When the concentration of the electrode component is assumed to be proportional to the battery capacity, and the value of “C_{A}/C_{A0}” is defined as the capacity residual rate of the battery, the capacity residual rate f(t) expressed by Formula (1) above can be derived on the basis of Formula (4) above.

f(t)=exp(−a×t) (1) (written again)

Formula (1) above can be expressed as Formula (5) below when being deformed using “1-exp(−a×t)” representing the first degradation rate defined above.

f(t)=1−{1−exp(−a×t)} (5)

Note that, hereinafter, “exp(−a×t)” in Formula (5) above may be referred to as a “first formula”, and “1−{1−exp(−a×t)}” may be referred to as a “first function formula”.

As shown in Formula (4) above, the reaction rate constant a is a coefficient to be multiplied by the time t. Therefore, in the battery 1 including the first degradation mechanism, the reaction rate constant a can be treated as a degradation coefficient that determines a degradation rate of the positive electrode. In this sense, the reaction rate constant is referred to as a “degradation coefficient” in the present specification. Note that, in order to distinguish from a degradation coefficient of the negative electrode described later, the degradation coefficient of the positive electrode may be referred to as a “first degradation coefficient”.

The degradation coefficient a has dependency on a temperature, and can be expressed by Formula (6) below in accordance with an Arrhenius equation having a frequency factor As and activation energy Es.

a=As×exp(−Es/RT) (6)

In Formula (6) above, reference character “R” is a gas constant, and reference character “T” is a temperature.

The activation energy Es and ln(As), which is a natural logarithmic value of the frequency factor As, have dependency on the charge rate SOC, and individually have a proportional relationship with the charge rate SOC.

Therefore, the activation energy Es can be expressed by a linear expression of the charge rate SOC as in Formula (7) below by using constants c and d.

Es=c×SOC+d (7)

Similarly, the frequency factor As can be expressed by a linear expression of the charge rate SOC as in Formula (8) below by using constants g and h.

ln(As)=g×SOC+h (8)

By using Formulas (6) to (8) above, the degradation coefficient a can be computed by measuring the temperature T of the battery 1 and the charge rate SOC of the battery 1, for the battery 1 including the first degradation mechanism.

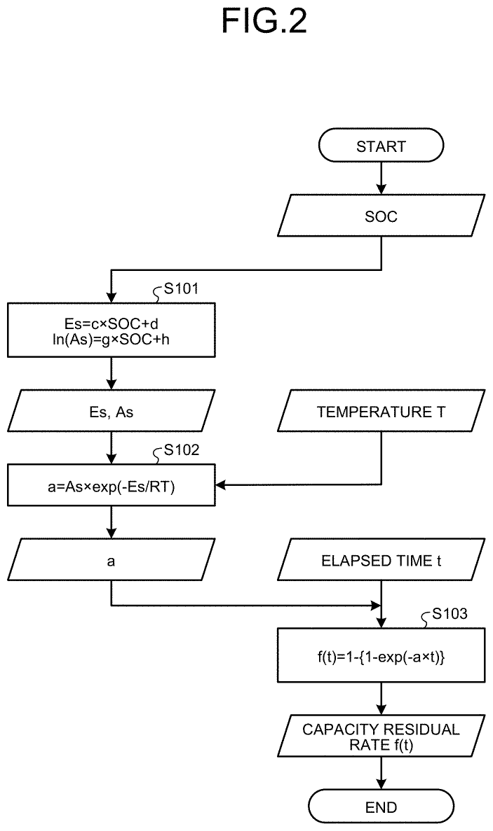

Next, a flow of degradation prediction processing in the battery degradation prediction device 10 according to the first embodiment will be described. FIG. 2 is a flowchart illustrating a processing flow of degradation prediction in the battery degradation prediction device according to the first embodiment. The processing of FIG. 2 is executed by the computing device 3.

In the processing of step S101, information on the charge rate SOC inputted from the battery monitoring device 2 is used. In step S101, the computing device 3 computes the activation energy Es and the natural logarithmic value ln(As) of the frequency factor As, on the basis of Formulas (7) and (8) above. The constants c, d, g, and h necessary for computation of the activation energy Es and the natural logarithmic value ln(As) of the frequency factor As can be prepared by performing a storage test on the battery to be predicted in advance.

In the processing of the next step S102, information on the activation energy Es and the frequency factor As computed in step S101 and information on the temperature T inputted from the battery monitoring device 2 are used. In step S102, the computing device 3 computes the degradation coefficient a on the basis of Formula (6) above.

In the processing of the next step S103, information on the degradation coefficient a computed in step S102 and information on the elapsed time t inputted from the battery monitoring device 2 are used. In step S103, the computing device 3 computes the capacity residual rate f(t) of the battery 1 at the elapsed time t on the basis of Formula (5) above or Formula (1) above. Note that, in a case where the battery 1 is in a non-use state, that is, in a storage state, the elapsed time is also referred to as a “storage time”.

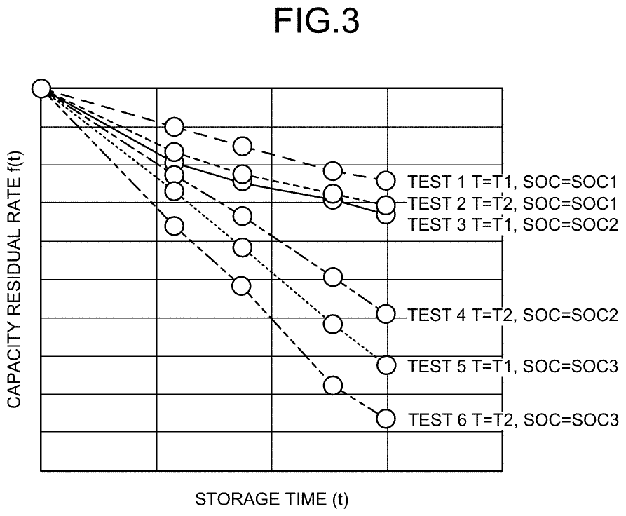

The constants c, d, g, and h to be used for computation of the degradation coefficient a are calculated in advance by, for example, experiment. Hereinafter, a specific processing procedure will be described with reference to FIG. 3. FIG. 3 is a graph to be used to describe a preliminary experiment in the first embodiment.

In FIG. 3, a horizontal axis represents the storage time t, and a vertical axis represents the capacity residual rate f(t). In addition, FIG. 3 indicates plotted values of the capacity residual rate f(t) according to test patterns of two levels for the temperature T, three levels for the charge rate SOC, and a total of 2×3=6 levels. Contents of each test pattern are as follows.

Test 1: T=T1, SOC=SOC1

Test 2: T=T2, SOC=SOC1

Test 3: T=T1, SOC=SOC2

Test 4: T=T2, SOC=SOC2

Test 5: T=T1, SOC=SOC3

Test 6: T=T2, SOC=SOC3

Note that, there is a relationship of T1<:T2 between T1 and T2. Further, there is a relationship of SOC1>SOC2>SOC3 among SOC1 to SOC3.

First, fitting is performed on a graph of Test 1 to Test 6 each with respect to f(t) by using a least squares method, and a value “a” is computed for each test. The value “a” is a value of the degradation coefficient a. The computed value “a” is held in the computing device 3.

Further, in individual plots of Test 1 to Test 6, capacity residual rates having equal SOC values and different temperatures T are extracted. Then, a natural logarithmic value ln(a) of the value “a” obtained above is plotted for a reciprocal 1/T of the temperature T in each test. Although detailed results here are omitted, a favorable linear relationship has been obtained by experiments by the inventors of the present application. As a result, it has been confirmed that a relationship between the degradation coefficient a, the frequency factor As, and the activation energy Es at an identical SOC value follows the Arrhenius equation.

The activation energy Es of electrode degradation at each SOC can be computed from a slope −Es/R (R: gas constant) of the obtained straight line. In addition, the frequency factor As of electrode degradation can be computed from an intercept ln(As) of the obtained straight line.

The activation energy Es and the frequency factor As in a case of other SOC values are also computed by a similar procedure. Each of the activation energy Es and the frequency factor As computed with several SOC values is plotted with respect to the SOC value. Although detailed results here are omitted, favorable linear approximate expressions are obtained for both the activation energy Es with respect to the SOC value and the frequency factor As with respect to the SOC value.

In the linear approximate expression of the activation energy Es with respect to the SOC value, a constant c can be obtained from a slope, and a constant d can be obtained from an intercept. In addition, in the linear approximate expression of the frequency factor As with respect to the SOC value, a constant g can be obtained from a slope, and a constant h can be obtained from an intercept.

By the above procedure, the constants c, d, g, and h can be prepared. Values of the computed constants c, d, g, and h are held in the computing device 3.

Further, the capacity residual rate f(t) at any elapsed time t can be computed by the following procedure.

First, the activation energy Es and the frequency factor As necessary for computing the degradation coefficient a are computed on the basis of SOC at a time of storage of the battery 1 to be predicted and the prepared constants c, d, g, and h. Next, the degradation coefficient a is computed on the basis of the computed activation energy Es and frequency factor As and the temperature T at the time of storage. Then, the capacity residual rate f(t) is computed on the basis of the computed degradation coefficient a and the elapsed time t. The capacity residual rate f(t) at any elapsed time t can be computed by the above procedure.

Further, when the capacity residual rate f(t) of the battery 1 is obtained, a residual capacity CAP of the battery 1 can be computed using Formula (9) below.

CAP=CAP_0×f(t) (9)

In the above Formula (9), CAP_0 is an initial capacity of the battery 1.

As described above, by using the technique of the first embodiment, the constants c, d, g, and h for obtaining the degradation coefficient a in a range of a storage schedule of the battery 1 can be obtained, by preliminarily performing a storage test under an environment with a small number of levels (six levels in the above example) of temperature and SOC at minimum in the range of the storage schedule of the battery 1. As a result, the degradation coefficient a at the elapsed time t can be computed by inputting the temperature T, the charge rate SOC, and the elapsed time t from the battery monitoring device 2 to the computing device 3. In addition, the capacity residual rate f(t) of the battery 1 and the residual capacity CAP of the battery 1 at the elapsed time t can be computed.

In a design stage of the battery 1, first, the capacity residual rate f(t) with a storage charge rate and a storage temperature at a scheduled time t is computed on the basis of the values of the constants c, d, g, and h and the degradation coefficient a prepared in the above procedure. Then, an initial capacity CAP_0 of the battery 1 is determined such that the residual capacity CAP of the battery 1 calculated by a product of the initial capacity CAP_0 of the battery 1 and the capacity residual rate f(t) becomes a necessary value required at the time t. Thus, an installation amount of the battery 1 can be determined.

As an example of a storage condition of the battery assumed at the design stage of the battery 1, a condition is considered in which the battery is stored with the charge rate SOC being SOC_1 and the temperature T being T_1 from a first time t_0 to a second time t_1, and with the charge rate SOC being SOC_2 and the temperature T being T_2 from the second time t_1 to a third time t_2. Under this storage condition, a capacity residual rate f(t)_1 at the second time t_1 can be computed using SOC_1 and T_1. Further, a residual capacity CAP_1 at the second time t_1 can be computed by a product of the capacity residual rate f(t)_1 and the initial capacity CAP_0. Similarly, a capacity residual rate f(t)_2 at the third time t_2 can be computed using SOC_2 and T_2. Further, a residual capacity CAP_2 at the third time t_2 can be computed by a product of the capacity residual rate f(t)_2 and the residual capacity CAP_1 at the second time t_1.

Even in a case where an environmental temperature is changed depending on an environment or season in which the battery 1 is installed, a residual capacity CAP_x at any time t_x can be computed by repeating similar computation on the basis of, for example, an average temperature for every month and a charge rate in the same period. Even in a case where the storage charge rate is scheduled to change, the residual capacity CAP_x at any time t_x can be computed by repeatedly performing similar computation processing.

As described above, in the design stage of the battery 1, as long as the temperature T and the charge rate SOC in the period of storage degradation are known in advance, the initial capacity CAP_0 can be determined so as to obtain the residual capacity CAP_x required at the time t_x at the end. Therefore, by using the technique of the first embodiment, it is possible to accurately estimate the necessary battery installation amount.

Further, when the battery 1 is in use, a storage temperature and a storage charge rate are monitored by the battery monitoring device 2. Here, it is assumed that the battery monitoring device 2 monitors that the battery has been stored with the charge rate SOC being SOC_3 and the temperature T being T_3 from a fourth time t_3 to a fifth time t_4. In this case, a capacity residual rate f(t)_3 at the fourth time t_3 can be computed by inputting actual measurement values of SOC_3 and T_3 from the fourth time t_3 to the fifth time t_4, to the computing device 3. Further, a residual capacity CAP_3 at the fourth time t_3 can be computed from a product of the capacity residual rate f(t)_3 and the initial capacity CAP_0.

Similarly, it is assumed that the battery monitoring device 2 monitors that the battery has been stored with the charge rate SOC being SOC_4 and the temperature T being T_4 from the fifth time t_4 to a sixth time t_5. In this case, a capacity residual rate f(t) 4 at the fifth time t_4 can be computed by inputting actual measurement values of SOC_4 and T_4 from the fifth time t_4 to the sixth time t_5, to the computing device 3. Further, a residual capacity CAP_4 at the fifth time t_4 can be computed from a product of the capacity residual rate f(t)_4 and the residual capacity CAP_3 at the fourth time t_3.

By repeatedly performing similar computation processing, the residual capacity CAP_x at any time t_x can be computed on the basis of information on the actually measured temperature T and charge rate SOC.

Note that, if the storage temperature and the storage charge rate assumed in the design stage are changed during the actual operation, a degradation state of the battery 1 is expected to be different from the state assumed in the design stage. Even in such a case, by inputting actual measurement values of the storage temperature and the storage charge rate to the computing device 3, the prediction value can be corrected in accordance with the actual operation.

Even in a case where a value of the residual capacity CAP_x at any time t_x is corrected in accordance with the actual operation, and then storage is continued from the time t_x to a time t_xx thereafter, similar prediction can be performed. First, a capacity residual rate f(t)_xx is computed on the basis of information on a storage charge rate SOC_xx and a temperature T_xx scheduled before the time t_xx. Next, CAP_xx is computed from a product of the residual capacity CAP_x and the capacity residual rate f(t)_xx at the time t_x. By performing similar processing and computing the capacity residual rate f(t) for each time zone, the residual capacity CAP_xx at any time t_xx can be computed even in a case where the scheduled storage charge rate and storage temperature are changed in a complicated manner.

By performing the above processing, even in a case where the initially assumed storage charge rate and storage temperature are changed during the storage period, the prediction value of the residual capacity of the battery 1 can be corrected by using the charge rate SOC and the temperature T actually measured with time. This makes it possible to predict the time of maintenance, inspection, replacement, and the like of the battery 1. Further, even when the storage conditions of the temperature T and the charge rate SOC are changed, the prediction value can be corrected.

As described above, according to the battery degradation prediction device according to the first embodiment, the computing device computes a capacity residual rate of the battery on the basis of a charge rate, a temperature, and an elapsed time from a start of monitoring the battery. The capacity residual rate is computed using the first function formula including the first formula. The first formula includes an exponential function having, as a variable, a value obtained by multiplying the elapsed time by a first degradation coefficient and −1. The battery degradation prediction device predicts a degradation state of the battery on the basis of the capacity residual rate computed using the first function formula. This makes it possible to predict a degradation state even when a target of the degradation prediction is a battery including the first degradation mechanism.

Further, according to the battery degradation prediction device according to the first embodiment, the computing device can compute the degradation coefficient a at the present time on the basis of the constants c, d, g, and h described above by using information on a temperature and a charge rate taken from the battery monitoring device, by an elapsed time before the present time. Then, on the basis of the computed degradation coefficient a at the present time, a current capacity residual rate and a future capacity residual rate at an elapsed time after the present time can be computed. This enables degradation prediction of the battery at any elapsed time under a condition where at least one of the temperature or the charge rate of the battery is different. In addition, by inputting an operation history so far and recalculating, it is possible to correct the computed value of the capacity residual rate of the battery and correct the degradation prediction. Further, also at the time of recalculation, the constants c, d, g, and h prepared in advance can be used by simply modifying the temperature, SOC, and the input value of the elapsed time. Since it is not necessary to prepare a new constant, it is possible to reduce a load on the computing device.

In addition, a preparation method for battery degradation prediction according to the first embodiment can be processing including first to seventh steps shown as follows. In the first step, the battery to be predicted is stored under a condition in which several points of a predetermined charge rate and several points of a predetermined temperature are combined. In the second step, a capacity residual rate of the battery is measured for each storage time. In the third step, a process of fitting a formula representing the capacity residual rate to a graph in which capacity residual rates are plotted for the storage time is performed. In the fourth step, a first degradation coefficient at any elapsed time is computed. In the fifth step, a frequency factor and activation energy are computed on the basis of a linear approximate expression obtained by extracting capacity residual rates having equal charge rates and different temperatures and plotting a natural logarithmic value of the first degradation coefficient obtained in the fourth step, with respect to a reciprocal of the temperature. In the sixth step, the frequency factor and the activation energy are computed with a charge rate different from the charge rate used in the fifth step. In the seventh step, a constant to be used in the battery degradation prediction is computed on the basis of a linear approximate expression obtained by plotting, with respect to the charge rate, the frequency factor and the activation energy obtained in the fifth and sixth steps. The above processing makes it possible to obtain a constant for obtaining the first degradation coefficient in a range of a storage schedule of the battery, by performing a storage test under an environment with a small number of levels of temperature and charge rate at minimum, in the battery in which the first degradation mechanism is a main factor of degradation. As a result, it is possible to compute the first degradation coefficient at the elapsed time by inputting a temperature, a charge rate, and an elapsed time from the battery monitoring device to the computing device, while reducing a load on the computing device. In addition, it is possible to compute the capacity residual rate of the battery and the residual capacity of the battery at the elapsed time, while reducing a load on the computing device.

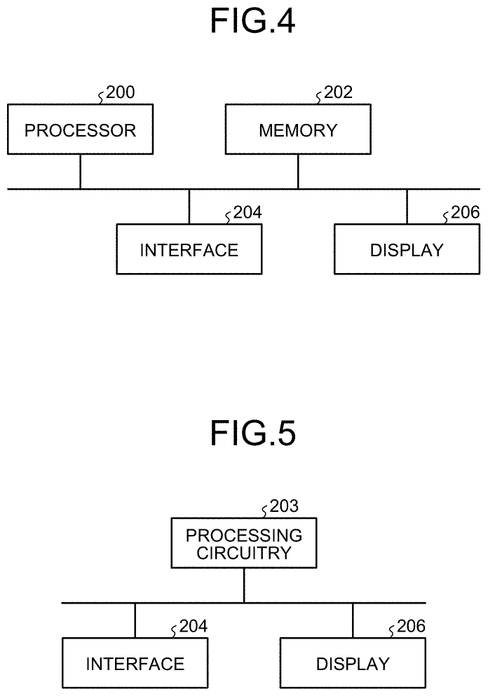

Next, a hardware configuration for implementing the function of the computing device in the first embodiment will be described with reference to FIGS. 4 and 5. FIG. 4 is a block diagram illustrating an example of a hardware configuration that implements the function of the computing device in the first embodiment. FIG. 5 is a block diagram illustrating another example of a hardware configuration that implements the function of the computing device in the first embodiment.

In a case where some or all of the functions of the computing device 3 in the first embodiment are implemented, as illustrated in FIG. 4, the configuration may include a processor 200, a memory 202, an interface 204 for input and output of signals, and a display 206 for display of computation information.

The processor 200 performs the above-described computation processing. The memory 202 stores a program that is read by the processor 200 and is for executing the function of the computing device 3 in the first embodiment. The memory 202 is also used as a work area for computation processing of the processor 200. The interface 204 provides an environment for signal input and output between the computing device 3 and the battery monitoring device 2. The display 206 displays a result of computation processing performed by the computing device 3 as necessary.

The processor 200 may be an arithmetic means such as a computing device, a microprocessor, a microcomputer, a central processing unit (CPU), or a digital signal processor (DSP). Further, examples of the memory 202 can include a nonvolatile or volatile semiconductor memory such as a random access memory (RAM), a read only memory (ROM), a flash memory, an erasable programmable ROM (EPROM), or an electrically EPROM (EEPROM, registered trademark), a magnetic disk, a flexible disk, an optical disk, a compact disk, a mini disk, and a digital versatile disc (DVD).

The processor 200 can perform the above-described processing by exchanging necessary information via the interface 204, causing the processor 200 to execute a program stored in the memory 202, and causing the processor 200 to refer to a table stored in the memory 202. The table stores the constants c, d, g, and h created in advance and constants i, j, m, and n to be used in a second embodiment described later. A computation result by the processor 200 can be stored in the memory 202.

In addition, in a case where some of the functions of the computing device 3 in the first embodiment are implemented, processing circuitry 203 illustrated in FIG. 5 can also be used. The processing circuitry 203 corresponds to a single circuit, a composite circuit, an application specific integrated circuit (ASIC), a field-programmable gate array (FPGA), or a combination of these. Information inputted to the processing circuitry 203 and information outputted from the processing circuitry 203 can be obtained via the interface 204.

Note that some of the processing in the computing device 3 may be performed by the processing circuitry 203, and processing that is not performed by the processing circuitry 203 may be performed by the processor 200 and the memory 202.

### Second Embodiment

Next, the second embodiment will be described. A configuration of a battery degradation prediction system including a battery degradation prediction device according to the second embodiment is identical to the configuration of the battery degradation prediction system 100 according to the first embodiment. A type of the battery 1 is different between the second embodiment and the first embodiment. In the second embodiment, portions different from those in the first embodiment will be mainly described, and redundant description will be omitted as appropriate.

The battery 1 in the second embodiment includes the first degradation mechanism described in the first embodiment. The battery 1 according to the second embodiment further includes a degradation mechanism in which a passive film (solid electrolyte interphase: SEI) grows on a negative electrode of the battery 1 to degrade a capacity. In the present specification, the degradation mechanism related to the negative electrode is appropriately referred to as a “second degradation mechanism”.

The battery monitoring device 2 monitors the charge rate SOC of the battery 1 and the temperature T of the battery 1. The computing device 3 receives information on the temperature T, the elapsed time t, and the charge rate SOC from the battery monitoring device 2. The elapsed time t is an elapsed time from when the battery monitoring device 2 starts monitoring the battery 1 or an elapsed time from previous reception to current reception. The computing device 3 in the second embodiment computes the capacity residual rate f(t) of the battery 1 with Formula (10) below on the basis of the charge rate SOC, the temperature T, and the elapsed time t.

f(t)=1−[{1−exp(−a×t)}+{b×t\hat{ }(½)}] (10)

Degradation of the negative electrode is caused by a growth of a passive film deposited on a surface of the negative electrode due to a side reaction of electrolytic solution. “b×t\hat{ }(½)” in Formula (10) above represents a degradation rate of the negative electrode in the second degradation mechanism. Hereinafter, the degradation rate of the negative electrode may be referred to as a “second degradation rate”.

In addition, hereinafter, “bxt\hat{ }(½)” in Formula (10) above may be referred to as a “second formula”, and the entire Formula (10) above may be referred to as a “second function formula”.

A coefficient b to be multiplied by a square root “t\hat{ }(½)” of the time t is a degradation coefficient that determines the degradation rate of the negative electrode. In this sense, the coefficient b is referred to as a “degradation coefficient b” in the present specification. Note that, in order to distinguish from the degradation coefficient a of the positive electrode, the degradation coefficient b may be referred to as a “second degradation coefficient”.

The degradation coefficient b has dependency on a temperature, and can be expressed by Formula (11) below in accordance with an Arrhenius equation having a frequency factor Af and activation energy Ef.

b=Af×exp(−Ef/RT) (11)

In Formula (11) above, reference character “R” is a gas constant, and reference character “T” is a temperature.

The activation energy Ef and ln(Af), which is a natural logarithmic value of the frequency factor Af, have dependency on the charge rate SOC, and individually have a proportional relationship with the charge rate SOC.

Therefore, the activation energy Ef can be expressed by a linear expression of the charge rate SOC as in Formula (12) below by using the constants i and j.

Ef=i×SOC+j (12)

Similarly, the frequency factor Af can be expressed by a linear expression of the charge rate SOC as in Formula (13) below by using the constants m and n.

ln(Af)=m×SOC+n (13)

By using Formulas (11) to (13) above, the degradation coefficient b can be computed by measuring the temperature T of the battery 1 and the charge rate SOC of the battery 1, for the battery including the second degradation mechanism.

Note that, in order to distinguish between the frequency factor As related to degradation of the positive electrode and the frequency factor Af related to degradation of the negative electrode, the former may be referred to as a “first frequency factor”, and the latter may be referred to as a “second frequency factor”. Further, in order to distinguish between the activation energy Es related to degradation of the positive electrode and the activation energy Ef related to degradation of the negative electrode, the former may be referred to as “first activation energy”, and the latter may be referred to as “second activation energy”.

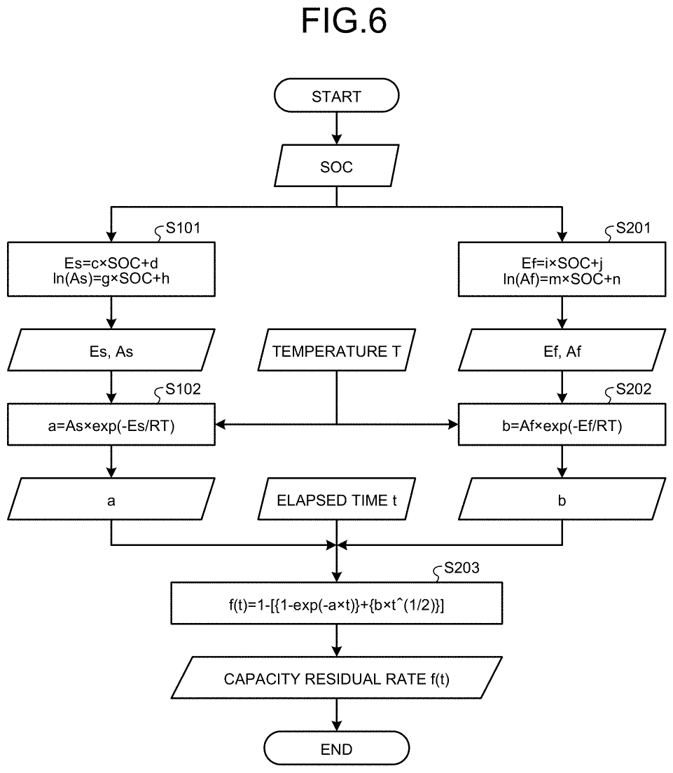

Next, a flow of degradation prediction processing in the battery degradation prediction device 10 according to the second embodiment will be described. FIG. 6 is a flowchart illustrating a processing flow of degradation prediction in the battery degradation prediction device according to the second embodiment. In FIG. 6, identical or equivalent processing contents to those in FIG. 2 are denoted by identical reference numerals to those in FIG. 2. The processing of FIG. 6 is executed by the computing device 3.

The processing in steps S101 and S102 is identical or equivalent to that in FIG. 2, and the description thereof will be omitted here. In step S201, the computing device 3 computes the activation energy Ef and the natural logarithmic value ln(Af) of the frequency factor Af, on the basis of Formulas (12) and (13) above. The constants i, j, m, and n necessary for computation of the activation energy Ef and the natural logarithmic value ln(Af) of the frequency factor Af can be prepared by performing a storage test on the battery to be predicted in advance.

In the processing of the next step S202, information on the activation energy Ef and the frequency factor Af computed in step S201 and information on the temperature T inputted from the battery monitoring device 2 are used. In step S202, the computing device 3 computes the degradation coefficient b on the basis of Formula (11) above.

In the processing of the next step S203, information on the degradation coefficient a computed in step S102, information on the degradation coefficient b computed in step S202, and information on the elapsed time t inputted from the battery monitoring device 2 are used. In step S203, the computing device 3 computes the capacity residual rate f(t) of the battery 1 at the elapsed time t on the basis of Formula (10) above.

The constants i, j, m, and n to be used for computation of the degradation coefficient b can be calculated in advance by a method similar to that in the first embodiment. A calculation technique is similar to that of the first embodiment, and the description thereof is omitted here. The constants c, d, g, h, i, j, m, and n calculated in advance are held in the computing device 3.

In the second embodiment, the capacity residual rate f(t) at any elapsed time t can be computed by the following procedure.

First, the activation energy Es and the frequency factor As necessary for computing the degradation coefficient a are computed on the basis of SOC at a time of storage of the battery 1 to be predicted and the prepared constants c, d, g, and h. Next, the degradation coefficient a is computed on the basis of the computed activation energy Es and frequency factor As and the temperature T at the time of storage. Similarly, the activation energy Ef and the frequency factor Af necessary for computing the degradation coefficient b are computed on the basis of SOC at a time of storage of the battery 1 to be predicted and the prepared constants i, j, m, and n. Then, the degradation coefficient b is computed on the basis of the computed activation energy Ef and frequency factor Af and the temperature T at the time of storage. Next, the capacity residual rate f(t) is computed on the basis of the computed degradation coefficients a and b and the elapsed time t. The capacity residual rate f(t) at any elapsed time t can be computed by the above procedure.

Further, when the capacity residual rate f(t) of the battery 1 is obtained, the residual capacity CAP of the battery 1 can be computed using Formula (9) above.

As described above, by using the technique of the second embodiment, the constants c, d, g, h, i, j, m, and n for obtaining the degradation coefficients a and b in a range of a storage schedule of the battery 1 can be obtained, by preliminarily performing a storage test under an environment with a small number of levels (six levels in the above example) of temperature and SOC at minimum in the range of the storage schedule of the battery 1. As a result, the degradation coefficients a and b at the elapsed time t can be computed by inputting the temperature T, the charge rate SOC, and the elapsed time t from the battery monitoring device 2 to the computing device 3. In addition, the capacity residual rate f(t) of the battery 1 and the residual capacity CAP of the battery 1 at the elapsed time t can be computed.

Note that considerations in the design stage of the battery 1, correction processing of a prediction value at the time of actual operation, and the like are equivalent to the contents described in the first embodiment, and description thereof here is omitted.

As described above, according to the battery degradation prediction device according to the second embodiment, the computing device computes a capacity residual rate of the battery on the basis of a charge rate, a temperature, and an elapsed time from a start of monitoring the battery. The capacity residual rate is computed using a second function formula including a first formula and a second formula. The first formula includes an exponential function having, as a variable, a value obtained by multiplying the elapsed time by a first degradation coefficient and −1. The second formula includes a square root function having, as a variable, a value obtained by multiplying a square root of the elapsed time by the second degradation coefficient. The battery degradation prediction device predicts a degradation state of the battery on the basis of the capacity residual rate computed using the second function formula. This makes it possible to predict a degradation state even when a target of the degradation prediction is a battery including the first and second degradation mechanisms.

Further, according to the battery degradation prediction device according to the second embodiment, by using information on the temperature and the charge rate taken from the battery monitoring device by an elapsed time before the present time, the computing device can compute the first and second degradation coefficients at the present time on the basis of the constants c, d, g, h, i, j, m, and n. Then, on the basis of the computed first and second degradation coefficients at the present time, a current capacity residual rate and a future capacity residual rate at an elapsed time after the present time can be computed. This enables degradation prediction of the battery at any elapsed time under a condition where at least one of the temperature or the charge rate of the battery is different. In addition, by inputting an operation history so far and recalculating, it is possible to correct the computed value of the capacity residual rate of the battery and correct the degradation prediction. Further, also at the time of recalculation, the constants c, d, g, h, i, j, m, and n prepared in advance can be used by simply modifying the temperature, SOC, and the input value of the elapsed time. Since it is not necessary to prepare a new constant, it is possible to reduce a load on the computing device.

In addition, a preparation method for battery degradation prediction according to the second embodiment can be processing including first to ninth steps shown as follows. In the first step, the battery to be predicted is stored under a condition in which several points of a predetermined charge rate and several points of a predetermined temperature are combined. In the second step, a capacity residual rate of the battery is measured for each storage time. In the third step, a process of fitting a formula representing the capacity residual rate to a graph in which capacity residual rates are plotted for the storage time is performed. In the fourth step, first and second degradation coefficients at any elapsed time are computed. In the fifth step, a first frequency factor and first activation energy are computed on the basis of a linear approximate expression obtained by extracting capacity residual rates having equal charge rates and different temperatures and plotting a natural logarithmic value of the first degradation coefficient obtained in the fourth step, with respect to a reciprocal of the temperature. In the sixth step, the first frequency factor and the first activation energy are computed with a charge rate different from the charge rate used in the fifth step. In the seventh step, a second frequency factor and second activation energy are computed on the basis of a linear approximate expression obtained by extracting capacity residual rates having equal charge rates and different temperatures and plotting a natural logarithmic value of the second degradation coefficient obtained in the fourth step, with respect to a reciprocal of the temperature. In the eighth step, the second frequency factor and the second activation energy are computed with a charge rate different from the charge rate used in the seventh step. In the ninth step, a constant to be used in the battery degradation prediction is computed on the basis of: a linear approximate expression obtained by plotting, with respect to the charge rate, the first frequency factor and the first activation energy obtained in the fifth and sixth steps; and a linear approximate expression obtained by plotting, with respect to the charge rate, the second frequency factor and the second activation energy obtained in the seventh and eighth steps. According to the processing described above, in the battery including the first degradation mechanism and the second degradation mechanism, it is possible to obtain a constant for obtaining the first degradation coefficient in a range of a storage schedule of the battery, by performing a storage test under an environment with a small number of levels of temperature and charge rate at minimum. As a result, it is possible to compute the first degradation coefficient at the elapsed time by inputting a temperature, a charge rate, and an elapsed time from the battery monitoring device to the computing device, while reducing a load on the computing device. In addition, it is possible to compute the capacity residual rate of the battery and the residual capacity of the battery at the elapsed time, while reducing a load on the computing device.

The configuration illustrated in the above embodiment illustrates one example and can be combined with another known technique, and it is also possible to combine embodiments with each other and omit and change a part of the configuration without departing from the subject matter of the present invention.

### REFERENCE SIGNS LIST

1 battery; 2 battery monitoring device; 3 computing device; 10 battery degradation prediction device; 100 battery degradation prediction system; 200 processor; 202 memory; 203 processing circuitry; 204 interface; 206 display.

1. A battery degradation prediction device for predicting a degradation state of a battery, the battery including a first degradation mechanism in which a capacity is degraded by elution of a part of a component of an electrode of the battery into a solution of the battery, the battery degradation prediction device comprising:
a battery monitor to monitor a charge rate of the battery and a temperature of the battery; and
a computer to compute a capacity residual rate of the battery based on the charge rate, the temperature, and an elapsed time from a start of monitoring of the battery, wherein
the capacity residual rate is computed using a first function formula including a first formula,
the first formula includes an exponential function having, as a variable, a value obtained by multiplying the elapsed time by a first degradation coefficient and −1, and
a degradation state of the battery is predicted based on the capacity residual rate computed using the first function formula.

2. The battery degradation prediction device according to claim 1, wherein
the first degradation coefficient is a degradation coefficient of a positive electrode that is degraded by the first degradation mechanism,
when the first degradation coefficient is represented by reference character “a” and the elapsed time is represented by reference character “t”, the first formula is represented by exp(−a×t) by using the elapsed time t,
a first degradation rate that is a capacity degradation rate of the battery caused by the first degradation mechanism is represented by 1−exp(−a×t) by using the first formula, and
a computation formula of the capacity residual rate is represented by 1−{1−exp(−a×t)} by using a formula representing the first degradation rate.

3. A battery degradation prediction device for predicting a degradation state of a battery, the battery including: a first degradation mechanism in which a capacity is degraded by elution of a part of a component of a positive electrode of the battery into a solution of the battery; and a second degradation mechanism in which the capacity is degraded by a growth of a passive film in a negative electrode of the battery, the battery degradation prediction device comprising:
a battery monitor to monitor a charge rate of the battery and a temperature of the battery; and
a computer to compute a capacity residual rate of the battery based on the charge rate, the temperature, and an elapsed time from a start of monitoring of the battery, wherein
the capacity residual rate is computed using a second function formula including a first formula and a second formula,
the first formula includes an exponential function having, as a variable, a value obtained by multiplying the elapsed time by a first degradation coefficient and −1,
the second formula includes a square root function having, as a variable, a value obtained by multiplying a square root of the elapsed time by a second degradation coefficient, and
a degradation state of the battery is predicted based on the capacity residual rate computed using the second function formula.

4. The battery degradation prediction device according to claim 3, wherein
the first degradation coefficient is a degradation coefficient of the positive electrode that is degraded by the first degradation mechanism,
when the first degradation coefficient is represented by reference character “a” and the elapsed time is represented by reference character “t”, the first formula is represented by exp(−a×t) by using the elapsed time t,
a first degradation rate that is a capacity degradation rate of the battery caused by the first degradation mechanism is represented by 1−exp(−a×t) by using the first formula, the second degradation coefficient is a degradation coefficient of the negative electrode,
when the second degradation coefficient is represented by reference character “b”, the second formula is represented by b×t\hat{ }(½) by using the elapsed time t,
the second formula represents a second degradation rate that is a capacity degradation rate of the battery caused by the second degradation mechanism, and
a computation formula of the capacity residual rate is expressed by 1−[{1−exp(−a×t)}+b×t\hat{ }(½)] by using a formula representing the first and second degradation rates.

5. The battery degradation prediction device according to claim 3, wherein
the first degradation coefficient a is expressed by Formula (1) below in accordance with an Arrhenius equation including activation energy Es and a frequency factor As,
the activation energy Es is expressed by Formula (2) below as a linear expression of a charge rate SOC by using constants c and d, and
a natural logarithmic value ln(As) of the frequency factor As is expressed by Formula (3) below as a linear expression of the charge rate SOC by using constants g and h, where
a=As×exp(−Es/RT) (1),
Es=c×SOC+d (2), and
ln(As)=g×SOC+h (3).

6. The battery degradation prediction device according to claim 5, wherein
the computer computes the first degradation coefficient a at present time based on the constants c, d, g, and h by using information on the temperature and the charge rate taken from the battery monitor by an elapsed time before present time, and the computer computes a current capacity residual rate and a future capacity residual rate at an elapsed time after present time, based on the first degradation coefficient a at the present time.

7. The battery degradation prediction device according to claim 5, wherein
the second degradation coefficient b is expressed by Formula (4) below in accordance with an Arrhenius equation including activation energy Ef and a frequency factor Af,
the activation energy Ef is expressed by Formula (5) below as a linear expression of a charge rate SOC by using constants i and j, and
a natural logarithmic value ln(Af) of the frequency factor Af is expressed by Formula (6) below as a linear expression of the charge rate SOC by using constants m and n, where
b=Af×exp(−Ef/RT) (4),
Ef=i×SOC+j (5), and
ln(Af)=m×SOC+n (6).

8. The battery degradation prediction device according to claim 7, wherein
the computer computes the first degradation coefficient a at present time and the second degradation coefficient b at present time based on the constants c, d, g, h, i, j, m, and n by using information on the temperature and the charge rate taken from the battery monitor by an elapsed time before present time, and the computer computes a current capacity residual rate and a future capacity residual rate at an elapsed time after present time, based on the first degradation coefficient a at the present time and the second degradation coefficient b at the present time.

9. A battery degradation prediction system comprising:
a battery; and
the battery degradation prediction device according to claim 1.

10. A preparation method for battery degradation prediction using the battery degradation prediction device according to claim 5, the preparation method comprising:
storing the battery to be predicted under a condition in which several points of a predetermined charge rate and several points of a predetermined temperature are combined;
measuring a capacity residual rate of the battery for each storage time;
fitting a formula representing a capacity residual rate to a graph in which the capacity residual rate is plotted for a storage time;
computing a first degradation coefficient at any elapsed time;
computing a frequency factor and activation energy based on a linear approximate expression, the linear approximate expression being obtained by extracting capacity residual rates having the charge rates that are equal and the temperatures that are different and plotting a natural logarithmic value of the first degradation coefficient obtained, with respect to a reciprocal of the temperature;
computing the frequency factor and the activation energy with a charge rate different from the charge rate used; and
computing a constant to be used in degradation prediction of the battery, based on a linear approximate expression obtained by plotting, with respect to the charge rate, the frequency factor and the activation energy obtained.

11. A preparation method for battery degradation prediction using the battery degradation prediction device according to claim 5, the preparation method comprising:
storing the battery to be predicted under a condition in which several points of a predetermined charge rate and several points of a predetermined temperature are combined;
measuring a capacity residual rate of the battery for each storage time;
fitting a formula representing a capacity residual rate to a graph in which a capacity residual rate is plotted for a storage time;
computing first and second degradation coefficients at any elapsed time;
computing a first frequency factor and first activation energy based on a linear approximate expression, the linear approximate expression being obtained by extracting capacity residual rates having the charge rates that are equal and the temperatures that are different and plotting a natural logarithmic value of the first degradation coefficient obtained, with respect to a reciprocal of the temperature;
computing the first frequency factor and the first activation energy with a charge rate different from the charge rate used;
computing a second frequency factor and second activation energy based on a linear approximate expression, the linear approximate expression being obtained by extracting capacity residual rates having the charge rates that are equal and the temperatures that are different and plotting a natural logarithmic value of the second degradation coefficient obtained, with respect to a reciprocal of the temperature;
computing the second frequency factor and the second activation energy with a charge rate different from the charge rate used; and
computing a constant to be used in degradation prediction of the battery, based on: a linear approximate expression obtained by plotting, with respect to the charge rate, the first frequency factor and the first activation energy obtained; and a linear approximate expression obtained by plotting, with respect to the charge rate, the second frequency factor and the second activation energy obtained.

12. A preparation method for battery degradation prediction using the battery degradation prediction device according to claim 7, the preparation method comprising:
storing the battery to be predicted under a condition in which several points of a predetermined charge rate and several points of a predetermined temperature are combined;
measuring a capacity residual rate of the battery for each storage time;
fitting a formula representing a capacity residual rate to a graph in which a capacity residual rate is plotted for a storage time;
computing first and second degradation coefficients at any elapsed time;
computing a first frequency factor and first activation energy based on a linear approximate expression, the linear approximate expression being obtained by extracting capacity residual rates having the charge rates that are equal and the temperatures that are different and plotting a natural logarithmic value of the first degradation coefficient obtained, with respect to a reciprocal of the temperature;
computing the first frequency factor and the first activation energy with a charge rate different from the charge rate used;
computing a second frequency factor and second activation energy based on a linear approximate expression, the linear approximate expression being obtained by extracting capacity residual rates having the charge rates that are equal and the temperatures that are different and plotting a natural logarithmic value of the second degradation coefficient obtained, with respect to a reciprocal of the temperature;
computing the second frequency factor and the second activation energy with a charge rate different from the charge rate used; and
computing a constant to be used in degradation prediction of the battery, based on: a linear approximate expression obtained by plotting, with respect to the charge rate, the first frequency factor and the first activation energy obtained; and a linear approximate expression obtained by plotting, with respect to the charge rate, the second frequency factor and the second activation energy obtained.

13. The battery degradation prediction device according to claim 1, wherein
the first degradation coefficient a is expressed by Formula (1) below in accordance with an Arrhenius equation including activation energy Es and a frequency factor As,
the activation energy Es is expressed by Formula (2) below as a linear expression of a charge rate SOC by using constants c and d, and
a natural logarithmic value ln(As) of the frequency factor As is expressed by Formula (3) below as a linear expression of the charge rate SOC by using constants g and h, where
a=As×exp(−Es/RT) (1),
Es=c×SOC+d (2), and
ln(As)=g×SOC+h (3).

14. A battery degradation prediction system comprising:
a battery; and
the battery degradation prediction device according to claim 3.
